(19) United States
(12) Patent Application Publication
(10) Pub. No.: US 2025/0046703 A1
(43) Pub. Date: Feb. 6, 2025

(54) SUBTRACTIVE METAL PATTERNING AND DAMASCENE-BASED INTERCONNECT

(71) Applicant: INTERNATIONAL BUSINESS MACHINES CORPORATION, ARMONK, NY (US)

(72) Inventors: Tao Li, Slingerlands, NY (US); Nicholas Anthony Lanzillo, Wynantskill, NY (US); Koichi Motoyama, Clifton Park, NY (US); Ruilong Xie, Niskayuna, NY (US)

(21) Appl. No.: 18/364,142

(22) Filed: Aug. 2, 2023

(51) Int. Cl. H01L 23/522; H01L 21/768

(52) U.S. Cl. CPC H01L 23/5226; H01L 21/76802; H01L 21/76831; H01L 21/76885

(57) ABSTRACT

Embodiments are disclosed for a semiconductor structure. The semiconductor structure includes a damascene-based interconnect. The damascene-based interconnect includes multiple metal layer Mx structures. Additionally, the semiconductor structure includes a subtractive metal patterned interconnect. The subtractive metal patterned interconnect includes multiple Vx-1 structures, multiple spacers in contact with the Vx-1 structures, and a dielectric liner. Further, the spacers and the dielectric liner prevent electrical contact between one of the Vx-1 structures and a neighboring Mx structure of the subtractive metal patterned layer.

### BACKGROUND

The present invention generally relates to semiconductor structures, and more particularly to metal connection between subtractive metal patterning and damascene-based interconnect for semiconductor structures.

Metal patterning is a semiconductor fabrication process whereby thin metal films are patterned through the deposition and removal of metal, and photolithography. In subtractive metal patterning, a thin film resist layer is patterned over a metal thin film. Additionally, the exposed portion of the metal thin film is then etched subtractively, and portions of the thin film resist layer is removed to produce a patterned metal layer. In contrast, a damascene-based interconnect is implemented in which metal is deposited into patterned channels in the inter-layer dielectric (ILD) layers and then planarized by chemical-mechanical polishing (CMP).

### SUMMARY

Embodiments are disclosed for a semiconductor structure. The semiconductor structure includes a damascene-based interconnect. The damascene-based interconnect includes multiple metal layer Mx structures. Additionally, the semiconductor structure includes a subtractive metal patterned interconnect. The subtractive metal patterned interconnect includes multiple Vx-1 structures, multiple spacers in contact with the Vx-1 structures, and a dielectric liner. Further, the spacers and dielectric liner prevent electrical contact between one of the Vx-1 structures and a neighboring Mx structure of the damascene-based metal patterned layer.

Embodiments are disclosed for a method of fabricating a semiconductor structure. The method includes performing an interlayer dielectric (ILD) fill and chemical mechanical planarization (CMP) of the ILD fill. The method also includes performing an ILD recess to reveal a Vx-1 structure of the semiconductor structure. Additionally, the method includes forming spacers around the Vx-1 structure. Further, the method includes performing selective removal of a first hard mask layer. Also, the method includes depositing an etch stop layer. Additionally, the method includes performing Mx patterning. Additionally, the method includes performing selective etching down of a second hard mask layer. Further, the method includes conformally depositing a dielectric liner to fill gaps in an ILD layer.

The present Summary is not intended to illustrate each aspect of, every implementation of, and/or every embodiment of the present disclosure. These and other features and advantages will become apparent from the following detailed description of the present embodiment(s), taken in conjunction with the accompanying drawings.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are illustrative of certain embodiments and do not limit the disclosure.

FIG. 1-1 is a cross-sectional view of semiconductor structures during intermediate steps of a method for forming a metal connection between subtractive metal patterning and Damascene-based interconnect, in accordance with some embodiments of the present disclosure.

FIG. 1-2 is a cross-sectional view of semiconductor structures during intermediate steps of a method for forming a metal connection between subtractive metal patterning and Damascene-based interconnect, in accordance with some embodiments of the present disclosure.

FIG. 1-3 is a cross-sectional view of semiconductor structures during intermediate steps of a method for forming a metal connection between subtractive metal patterning and Damascene-based interconnect, in accordance with some embodiments of the present disclosure.

FIG. 1-4 is a cross-sectional view of semiconductor structures during intermediate steps of a method for forming a metal connection between subtractive metal patterning and Damascene-based interconnect, in accordance with some embodiments of the present disclosure.

FIG. 1-5 is a cross-sectional view of semiconductor structures during intermediate steps of a method for forming a metal connection between subtractive metal patterning and Damascene-based interconnect, in accordance with some embodiments of the present disclosure.

FIG. 1-6 is a cross-sectional view of semiconductor structures during intermediate steps of a method for forming a metal connection between subtractive metal patterning and Damascene-based interconnect, in accordance with some embodiments of the present disclosure.

FIG. 1-7 is a cross-sectional view of semiconductor structures during intermediate steps of a method for forming a metal connection between subtractive metal patterning and Damascene-based interconnect, in accordance with some embodiments of the present disclosure.

FIG. 1-8 is a cross-sectional view of semiconductor structures during intermediate steps of a method for forming a metal connection between subtractive metal patterning and Damascene-based interconnect, in accordance with some embodiments of the present disclosure.

FIG. 1-9 is a cross-sectional view of semiconductor structures during intermediate steps of a method for forming a metal connection between subtractive metal patterning and Damascene-based interconnect, in accordance with some embodiments of the present disclosure.

FIG. 1-10 is a cross-sectional view of semiconductor structures during intermediate steps of a method for forming a metal connection between subtractive metal patterning and Damascene-based interconnect, in accordance with some embodiments of the present disclosure.

FIG. 1-11 is a cross-sectional view of semiconductor structures during intermediate steps of a method for forming a metal connection between subtractive metal patterning and Damascene-based interconnect, in accordance with some embodiments of the present disclosure.

FIG. 1-12 is a cross-sectional view of semiconductor structures during intermediate steps of a method for forming a metal connection between subtractive metal patterning and Damascene-based interconnect, in accordance with some embodiments of the present disclosure.

FIG. 2 is a process flow chart of a method for forming a metal connection between subtractive metal patterning and Damascene-based interconnect, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the example embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub lithographic” may refer to a dimension or size less than current dimensions achievable by photolithographic processes, and the term “lithographic” may refer to a dimension or size equal to or greater than current dimensions achievable by photolithographic processes. The sub lithographic and lithographic dimensions may be determined by a person of ordinary skill in the art at the time the application is filed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device having a dummy fin removed from within an array of tight pitch fins according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As stated previously, metal patterning is a semiconductor fabrication process whereby thin metal films are patterned through the deposition and removal of metal, and photolithography. In subtractive metal patterning, a thin film resist layer is patterned over a metal thin film. Additionally, the exposed portion of the metal thin film is then etched subtractively, and portions of the thin film resist layer is removed to produce a patterned metal layer. In contrast, a damascene-based interconnect is implemented in which metal is deposited into patterned channels in the inter-layer dielectric (ILD) layers and then planarized by chemical-mechanical polishing (CMP). However, during fabrication, the alignment of the patterned metal layer (metal layer) and interconnect may vary. In some cases, a relative misalignment may result in a patterned metal layer that shorts with the interconnect. Further, even in cases where the metal layer may not short, the contact area between the metal connection, metal layer, and interconnect, may be lower than the contact area in a relative alignment of the metal layer and the interconnect.

Accordingly, some embodiments of the present disclosure provide a semiconductor structure having metal connection that provides an increased amount of contact with a patterned metal layer and a Damascene-based interconnect. Further, in such embodiments, the metal connection that does not create a short between the metal layer and interconnect, despite any potential misalignment. Semiconductor structures fabricated with such embodiments provide an improvement in the operation of semiconductor structures having such metal connections. However, some embodiments of the present disclosure may not achieve such advantages.

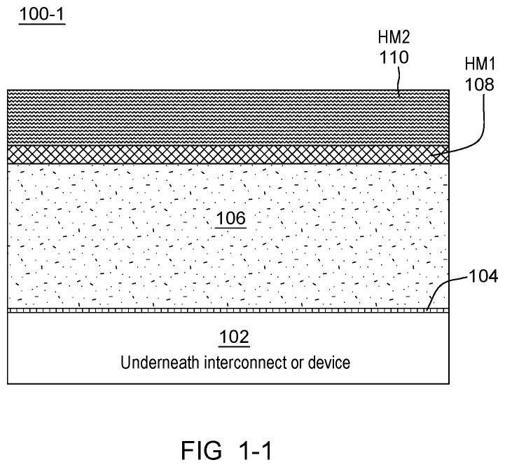

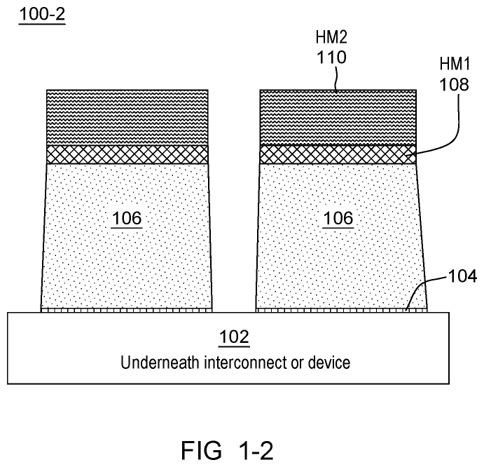

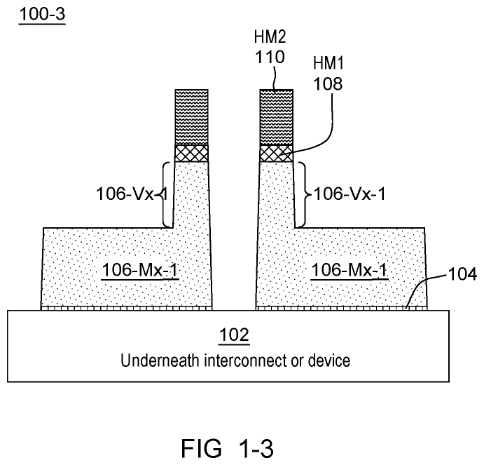

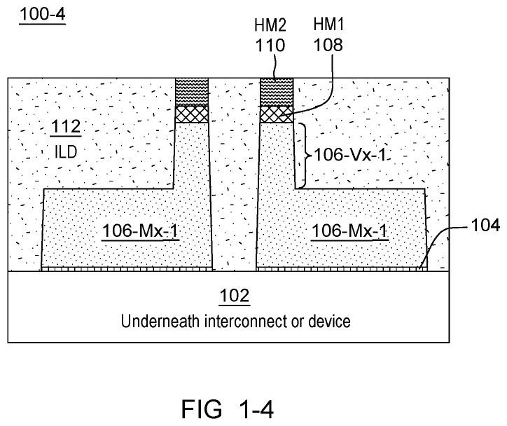

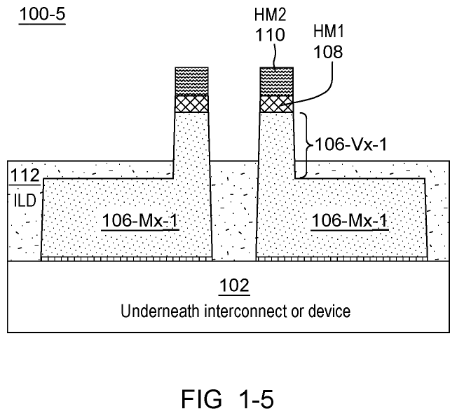

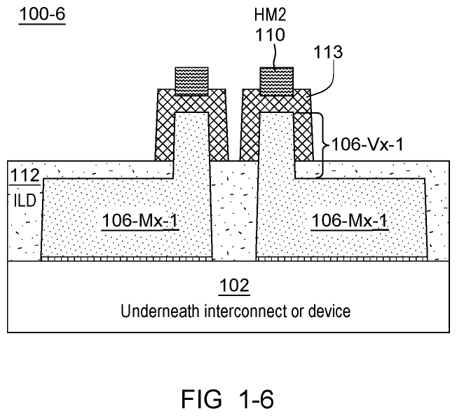

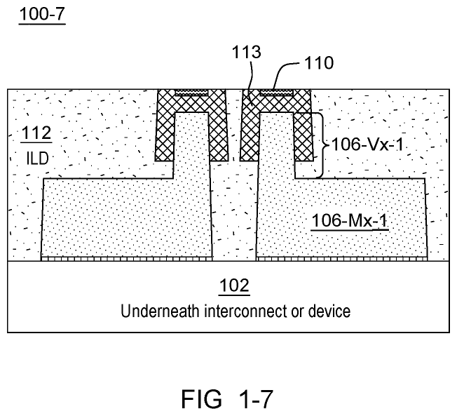

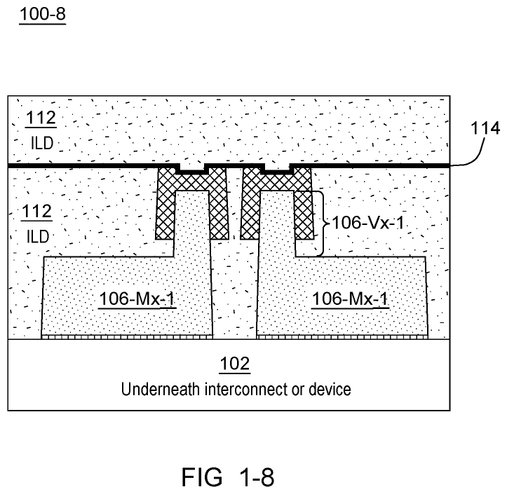

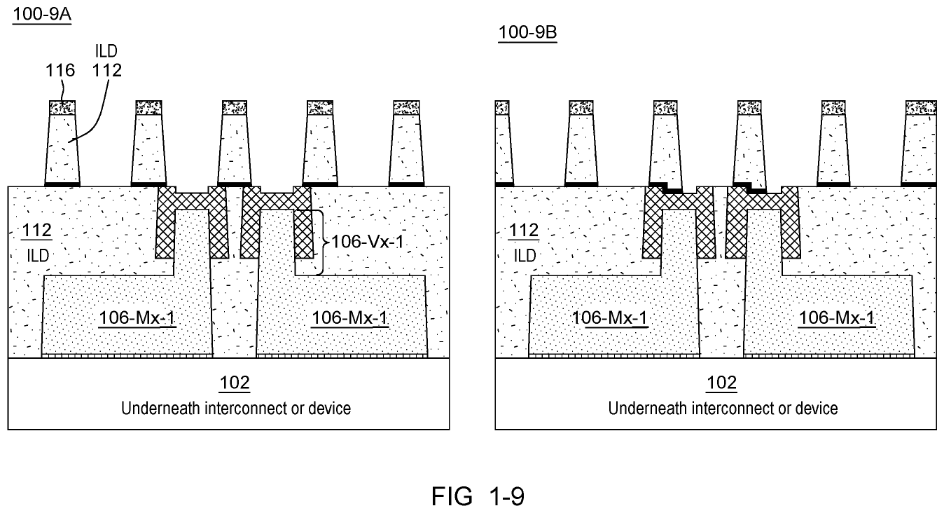

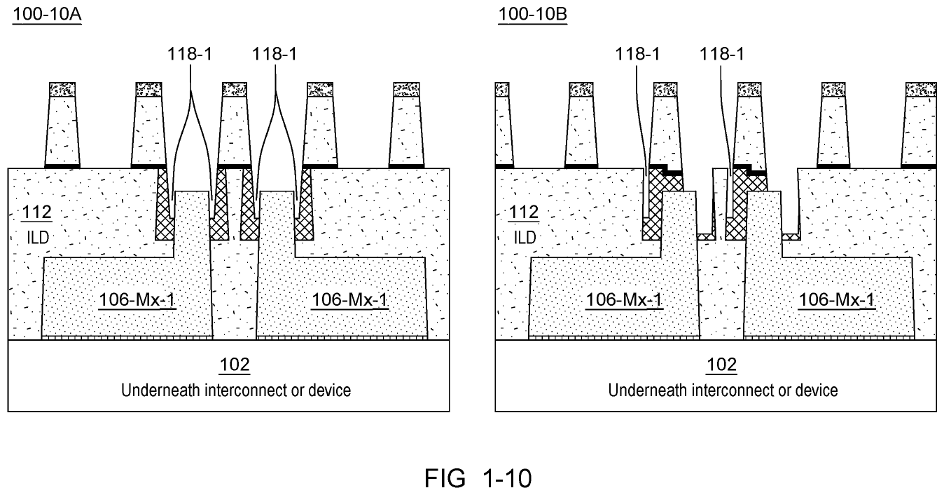

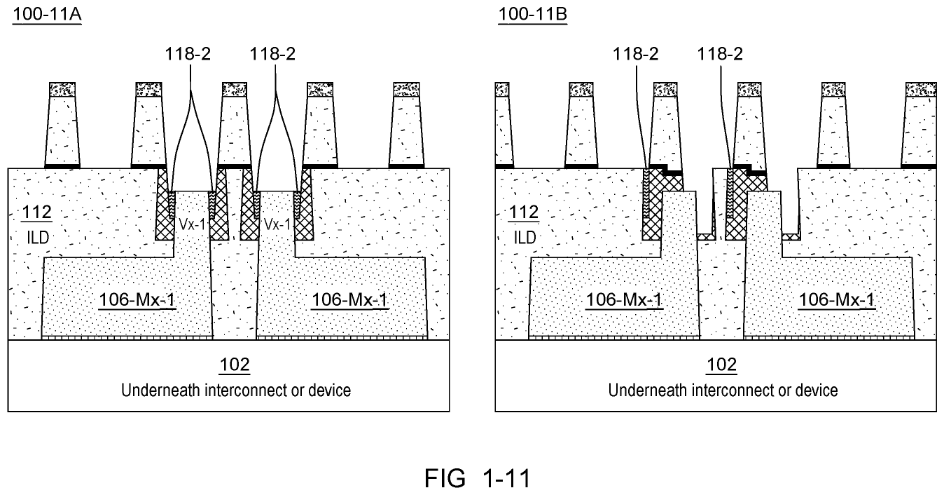

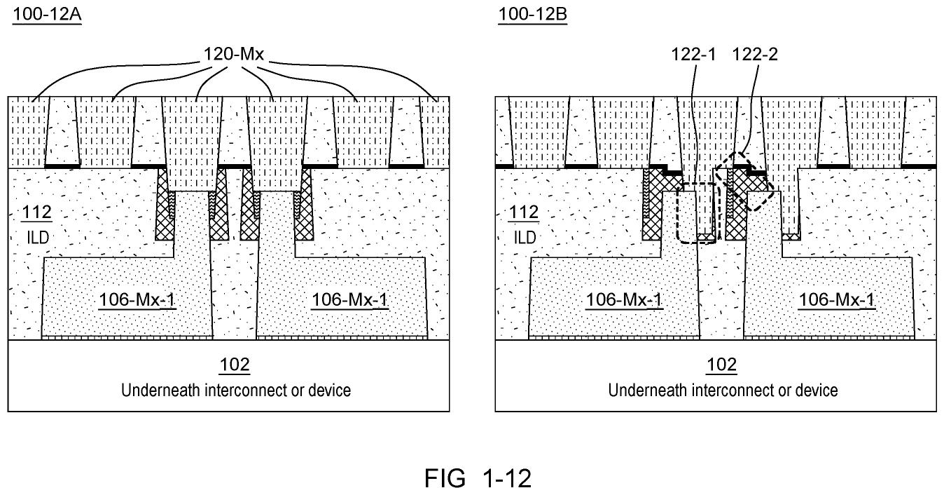

FIGS. 1-1 through 1-12 are cross-sectional views of example semiconductor structures 100-1 through 100-12 produced by a fabrication process for forming a metal connection between subtractive metal patterning and Damascene-based interconnect, in accordance with some embodiments of the present disclosure. For clarity, not all elements are labelled in these figures. Rather, representative elements are labelled, with similar elements being indicated by position, size, shape, hash lines (or lack thereof), and the like, in subsequent figures.

FIG. 1-1 is a cross-sectional view of a semiconductor structure 100-1 during intermediate steps of a method for forming a metal connection between subtractive metal patterning and Damascene-based interconnect, in accordance with some embodiments of the present disclosure. The semiconductor structure 100-1 may result from a fabrication method wherein materials constituting each of these elements is deposited, applied, and otherwise arranged as shown. For example, the semiconductor structure 100-1 includes an underneath interconnect or device layer 102, adhesion metal liner 104, metal layer 106, first hard mask (HM1) 108, and second hard mask (HM2) 110. The underneath interconnect or device layer 102 can be an interconnect, such as, a back end of line structure, backside power distribution network; or a device, such as, transistors, capacitors, resistors, diodes, and the like. The underneath interconnect or device layer 102 can be a wafer frontside back-end-of-line (BEOL) layer, wafer backside interconnect layer, and the like. Further, the adhesion metal liner 104 can be a thin layer of titanium nitride (TiN), tantalum nitride (TaN), or the like. Additionally, the metal layer 106 can be a metal, such as, ruthenium (Ru). Also, the HM1 108 may include a nitride, such as, silicon carbon nitride (SiCN). Further, the HM2 110 may include an oxide, such as, silicon carbon oxide (SiCO).

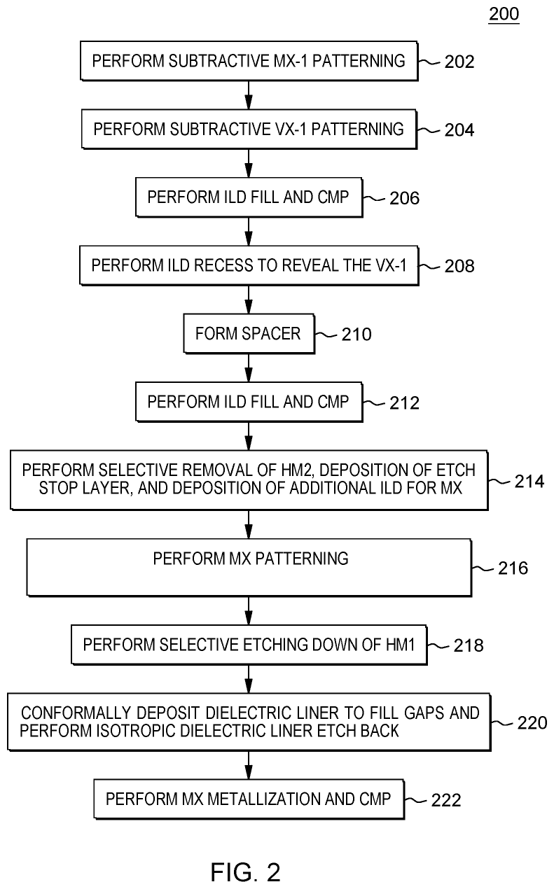

FIG. 1-2 is a cross-sectional view of a semiconductor structure 100-2 during intermediate steps of a method for forming a metal connection between subtractive metal patterning and Damascene-based interconnect, in accordance with some embodiments of the present disclosure. The semiconductor structure 100-2 results from performing subtractive Mx-1 patterning on the semiconductor structure 100-1. Performing subtractive Mx-1 patterning involves removing portions of the adhesion metal liner 104, metal layer 106, HM1 108, and HM2 110.

FIG. 1-3 is a cross-sectional view of a semiconductor structure 100-3 during intermediate steps of a method for forming a metal connection between subtractive metal patterning and Damascene-based interconnect, in accordance with some embodiments of the present disclosure. The semiconductor structure 100-3 results from performing subtractive Vx-1 patterning on the semiconductor structure 100-2. Performing subtractive Vx-1 patterning involves removing portions of the metal layer 106, HM1 108, and HM2 110 to form the structures 106-Mx-1 and structures 106-Vx-1.

FIG. 1-4 is a cross-sectional view of a semiconductor structure 100-4 during intermediate steps of a method for forming a metal connection between subtractive metal patterning and Damascene-based interconnect, in accordance with some embodiments of the present disclosure. The semiconductor structure 100-4 results from performing an interlayer dielectric (ILD) fill and chemical-mechanical planarization (CMP) on the semiconductor structure 100-3. Performing the ILD fill involves depositing an ILD material on and around the structures 106-Mx-1 and structures 106-Vx-1 to form the ILD layer 112. Additionally, performing CMP involves chemical etching and mechanical removal of portions of the deposited ILD material to form a planarized surface for the ILD layer 112 with the HM2 110.

FIG. 1-5 is a cross-sectional view of a semiconductor structure 100-5 during intermediate steps of a method for forming a metal connection between subtractive metal patterning and Damascene-based interconnect, in accordance with some embodiments of the present disclosure. The semiconductor structure 100-5 results from performing an ILD recess on the semiconductor structure 100-4. Performing the ILD recess involves removing portions of the ILD layer 112 to reveal the structures 106-Vx-1.

FIG. 1-6 is a cross-sectional view of a semiconductor structure 100-6 during intermediate steps of a method for forming a metal connection between subtractive metal patterning and Damascene-based interconnect, in accordance with some embodiments of the present disclosure. The semiconductor structure 100-6 results from forming spacers 113 on the semiconductor structure 100-5. Forming the spacers 113 involves depositing the material of the HM1 108 around the HM1 108 and the structures 106-Vx-1 followed by an anisotropic etch process, e.g. a reactive ion etch (RIE) process.

FIG. 1-7 is a cross-sectional view of a semiconductor structure 100-7 during intermediate steps of a method for forming a metal connection between subtractive metal patterning and Damascene-based interconnect, in accordance with some embodiments of the present disclosure. The semiconductor structure 100-7 results from performing an ILD fill and CMP on the semiconductor structure 100-6. In this ILD fill and CMP, performing the ILD fill involves depositing ILD material around the structures 106-Vx-1, spacers 113, and HM2 110. Additionally, performing the CMP involves removing material from the top ILD layer and HM1 110 to form a planarized surface for the ILD layer 112 and the remaining material of the HM2 110. Further, the semiconductor structure 100-7 represents a substractive etch-based interconnect to the underneath interconnect 102.

FIG. 1-8 is a cross-sectional view of a semiconductor structure 100-8 during intermediate steps of a method for forming a metal connection between subtractive metal patterning and Damascene-based interconnect, in accordance with some embodiments of the present disclosure. The semiconductor structure 100-8 results from performing selective removal of the HM2 110, depositing an etch stop layer 114, and depositing an additional ILD layer 112 on the etch stop layer 114. The etch stop layer 114 may be composed of an aluminum nitride (AlNx) or aluminum oxide (AlOx) compound, and the like.

FIG. 1-9 is a cross-sectional view of semiconductor structures 100-9A, 100-9B during intermediate steps of a method for forming a metal connection between subtractive metal patterning and Damascene-based interconnect, in accordance with some embodiments of the present disclosure. The semiconductor structures 100-9A, 100-9B result from performing Mx metal layer patterning on the semiconductor structure 100-8. As stated previously, during fabrication, the alignment of the patterned metal layer (metal layer) and subtractive etch-based interconnect may vary. Accordingly, the semiconductor structure 100-9A may represent one potential alignment scenarios that may not result in potential shorts. Additionally, the semiconductor structure 100-9B may represent a potential misalignment scenario that may result in potential shorts with the subtractive etch-based interconnect and a damascene-based patterned metal layer. Performing patterning may involve removing ILD material from the ILD layer 112, and the etch stop layer 114. Removing the ILD material may result in pillar like structures in the top ILD layer. Additionally, patterning may involve depositing material for hard mask 116 on the top ILD layer.

FIG. 1-10 is a cross-sectional view of semiconductor structures 100-10A, 100-10B during intermediate steps of a method for forming a metal connection between subtractive metal patterning and Damascene-based interconnect, in accordance with some embodiments of the present disclosure. The semiconductor structures 100-10A, 100-10B result from selective etching of the HM1 108 and a portion of spacer 113 on the semiconductor structures 100-9A, 100-9B, respectively. Selective etching of the HM1 108 may involve removing material from the HM1 108 to expose the structures 106-Vx-1 beneath the pillars of the top ILD layer. As shown, the selective etching may leave gaps 118-1 (e.g., between the remaining material of the spacers 113, the structures 106-Vx-1, and the bottom ILD layer).

FIG. 1-11 is a cross-sectional view of semiconductor structures 100-11A, 100-11B during intermediate steps of a method for forming a metal connection between subtractive metal patterning and Damascene-based interconnect, in accordance with some embodiments of the present disclosure. The semiconductor structures 100-11A, 100-11B result from conformally depositing dielectric liner 118-2 to fill the gaps of the semiconductor structures 100-10A, 100-10B, respectively. Additionally, the semiconductor structures 100-11A, 100-11B may result from isotropic dielectric liner etch back on the conformally deposited dielectric liner.

FIG. 1-12 is a cross-sectional view of semiconductor structures 100-12A, 100-12B during intermediate steps of a method for forming a metal connection between subtractive metal patterning and Damascene-based interconnect, in accordance with some embodiments of the present disclosure. The semiconductor structures 100-12A, 100-12B result from Mx metallization and CMP on the semiconductor structures 100-11A, 100-11B, respectively. The Mx metallization may form the metal structures 120-Mx. In the view of the semiconductor structure 100-12B of the misalignment scenario, box 122-1 indicates a contact area between the structure 106-Vx-1 and the metal structure 120-Mx, which represents an increased amount of contact area in comparison to semiconductor structures fabricated using prior techniques. Additionally, box 122-2 indicates the distance between the structure 106-Vx-1 and the neighboring metal structure 120-Mx, eliminating (e.g., preventing) any potential shorts from the misalignment.

FIG. 2 is a process flow chart of a method 200 for forming a metal connection between subtractive metal patterning and Damascene-based interconnect, in accordance with some embodiments of the present disclosure. The method 200 may be similar to the method represented in FIGS. 1-1 through 1-12, to produce a semiconductor structure, such as the example semiconductor structures 100-12A, 100-12B.

At operation 202, a fabrication tool can perform subtractive Mx-1 patterning, described with respect to FIG. 1-2. As stated previously, performing subtractive Mx-1 patterning involves removing portions of the adhesion metal liner 104, metal layer 106, HM1 108, and HM2 110.

At operation 204, a fabrication tool may perform subtractive Vx-1 patterning. As stated previously, performing subtractive Vx-1 patterning can involve removing portions of the metal layer 106, HM1 108, and HM2 110 to form the structures 106-Mx-1 and structures 106-Vx-1.

At operation 206, a fabrication tool can perform ILD fill and CMP. As stated previously, performing ILD fill and CMP can involve depositing an ILD material on and around the structures 106-Mx-1 and structures 106-Vx-1 to form the ILD layer 112. Additionally, performing CMP involves chemical etching and mechanical removal of portions of the deposited ILD material to form a planarized surface for the ILD layer 112 with the HM2 110.

At operation 208, a fabrication tool can perform ILD recess to reveal the Vx-1. Performing the ILD recess involves removing portions of the ILD layer 112 to reveal the structures 106-Vx-1.

At operation 210, a fabrication tool can form spacers, such as the spacers 113. Forming the spacers 113 involves depositing the material of the HM1 108 around the ILD layer 112, HM1 108, HM2 110 and the structures 106-Vx-1, followed by an anisotropic etch process, such as a reactive ion etch (RIE).

At operation 212, a fabrication tool can perform another ILD fill and CMP. In this operation, performing the ILD fill involves depositing ILD material around the structures 106-Vx-1, spacers 113, and HM2 110. Additionally, performing the CMP involves removing material from the top ILD layer and HM2 110 to form a planarized surface for the ILD layer 112 and the remaining material of the HM2 110.

At operation 214, a fabrication tool can perform selective removal of HM2 110, deposition of etch stop layer 114, and deposition of additional ILD for Mx. The etch stop layer 114 is deposited on the lower ILD layer, HM1 108, spacers 113. Further, the additional ILD layer is deposited on the etch stop layer 114.

At operation 216, a fabrication tool can perform Mx patterning. Performing Mx patterning may involve removing ILD material from the top ILD layer, and the etch stop layer 114. As shown in FIG. 1-9, removing the ILD material may result in pillar like structures in the top ILD layer. Additionally, patterning may involve depositing material for hard mask 116 on the top ILD layer.

At operation 218, a fabrication tool can perform selective etching down of HM1 108. Selective etching of the HM1 108 may involve removing material from the HM1 108 to expose the structures 106-Vx-1 beneath the pillars of the top ILD layer. As stated previously, the selective etching may leave gaps 118-1 (e.g., between the remaining material of the spacers 113, the structures 106-Vx-1, and the bottom ILD layer).

At operation 220, a fabrication tool can conformally deposit dielectric liner to fill the gaps 118-1. Additionally, operation 220 can involve performing isotropic dielectric liner etch back.

At operation 222, a fabrication tool can perform Mx metallization and CMP. The Mx metallization may form the metal structures 120-Mx, as described with respect to FIG. 1-12.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks. When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category. For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations. Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to one skilled in the art. Therefore, it is intended that the following claims be interpreted as covering all such alterations and modifications as fall within the true spirit and scope of the invention.

What is claimed is:

1. A semiconductor structure comprising:
a damascene-based interconnect layer comprising a plurality of metal layer Mx structures; and
a subtractive metal patterned interconnect, comprising:
a plurality of Vx-1 structures;
a plurality of spacers in contact with the plurality of Vx-1 structures; and
a dielectric liner, wherein the plurality of spacers and the dielectric liner prevent electrical contact between one of the Vx-1 structures and a neighboring Mx structure of the damascene-based metal patterned layer.

2. The semiconductor structure of claim 1, further comprising an underneath interconnect in contact with the subtractive metal patterned interconnect.

3. The semiconductor structure of claim 2, wherein the underneath interconnect is selected from a group consisting of a wafer frontside back-end-of-line (BEOL) layer or wafer backside interconnect layer.

4. The semiconductor structure of claim 1, further comprising a semiconductor device in contact with the subtractive metal patterned interconnect.

5. The semiconductor structure of claim 4, wherein the semiconductor device is selected from a group consisting of a transistor, capacitor, resistor, and diode.

6. The semiconductor structure of claim 1, wherein the damascene-based interconnect is misaligned with the subtractive metal patterned interconnect.

7. The semiconductor structure of claim 1, wherein the damascene-based interconnect is aligned with the subtractive metal patterned interconnect.

8. The semiconductor structure of claim 1, comprising a plurality of hard masks disposed on top of the plurality of Vx-1 structures.

9. The semiconductor structure of claim 1, wherein a plurality of hard masks comprise a material, wherein the spacers comprise the material.

10. The semiconductor structure of claim 1, wherein each of the plurality of spacers comprise one of the plurality of hard masks.

11. A semiconductor structure comprising:
a damascene-based interconnect layer comprising a plurality of metal layer Mx structures; and
a subtractive metal patterned interconnect, wherein the damascene-based interconnect is misaligned with the subtractive metal patterned interconnect, and wherein the subtractive metal patterned interconnect comprises:
a plurality of Vx-1 structures;
a plurality of spacers in contact with the plurality of Vx-1 structures;
an underneath interconnect in contact with the subtractive metal patterned interconnect; and
a dielectric liner, wherein the plurality of spacers and the dielectric liner prevent electrical contact between one of the Vx-1 structures and a neighboring Mx structure of the damascene-based metal patterned layer.

12. The semiconductor structure of claim 11, further comprising a semiconductor device in contact with the subtractive metal patterned interconnect.

13. The semiconductor structure of claim 12, wherein the semiconductor device is selected from a group consisting of a transistor, capacitor, resistor, and diode.

14. The semiconductor structure of claim 11, further comprising an underneath interconnect in contact with the subtractive metal patterned interconnect, wherein the underneath interconnect is selected from a group consisting of a wafer frontside back-end-of-line (BEOL) layer and wafer backside interconnect layer.

15. The semiconductor structure of claim 11, comprising a plurality of hard masks disposed on top of the plurality of Vx-1 structures.

16. The semiconductor structure of claim 11, wherein a plurality of hard masks comprise a material, wherein the spacers comprise the material.

17. The semiconductor structure of claim 16, wherein each of the plurality of spacers comprise one of the plurality of hard masks.

18. A method for fabricating a semiconductor structure, the method comprising:
performing an interlayer dielectric (ILD) fill and chemical mechanical planarization (CMP) of the ILD fill;
performing an ILD recess to reveal a Vx-1 structure of the semiconductor structure;
forming spacers around the Vx-1 structure;
performing selective removal of a first hard mask layer;
depositing an etch stop layer;
performing Mx patterning;
performing selective etching down of a second hard mask layer; and
conformally depositing a dielectric liner to fill gaps in an ILD layer.

19. The method of claim 18, further comprising performing an isotropic etch back of the dielectric liner.

20. The method of claim 19, further comprising performing Mx metallization and CMP of the Mx metallization.
